(19) United States
(12) Patent Application Publication
(10) Pub. No.: US 2009/0078563 A1
(43) Pub. Date: Mar. 26, 2009

(54) Plasma Processing Apparatus And Method Capable of Adjusting Temperature Within Sample Table

(76) Inventors: Tooru Aramaki, Kudamatsu (JP); Tsunehiko Tsubone, Kudamatsu (JP); Tadamitsu Kanekiyo, Kudamatsu (JP); Kenetsu Yokogawa, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/267,880

(22) Filed: Nov. 10, 2008

Related U.S. Application Data
(62) Division of application No. 11/209,743, filed on Aug. 24, 2005.

(30) Foreign Application Priority Data
Jun. 17, 2005 (JP) 2005-177116

(51) Int. Cl. C23C 14/28

(52) U.S. Cl. 204/192.1

(57) ABSTRACT

A plasma processing method includes mounting a workpiece to be processed on an upper surface of a sample table disposed at a lower portion of an interior of a processing chamber disposed within a vacuum vessel and processing the workpiece by use of plasma formed within the processing chamber while applying thereto a first high frequency power for adjustment of a surface potential of the workpiece which is disposed on the sample table. The method further includes starting, prior to application of the first high frequency power, to adjust a temperature of a heat exchange medium flowing in a passage disposed inside of the sample table so as to have a predetermined value based on information of this high frequency power.

### BACKGROUND OF THE INVENTION

The present invention relates to plasma processing apparatus and method for processing a specimen or sample mounted on a top surface of a sample support table within a processing chamber by use of a plasma as formed in a vacuum vessel. This invention also relates to a technique for processing samples by adjusting a temperature within the sample table while simultaneously applying high frequency power to an electrode within the sample table.

The so-called plasma processing apparatus is for forming a plasma in the inner space of a processing chamber within a vacuum vessel and then applying plasma processing to an object to be processed—i.e., a workpiece or specimen, also called a sample—such as a semiconductor wafer or substrate, which is mounted on a sample support table that is disposed at a lower part of this processing chamber. In this apparatus, with an increase in integration density of semiconductor devices to be fabricated through several processing steps, it has been required at higher standards to achieve miniaturization and high precision of the processing.

In order for such the apparatus to perform ultra-fine or more highly accurate processing, it becomes necessary to further uniformize the plasma processing with respect to surface directions of a workpiece such as a wafer or substrate or else. For example, once the uniformity is lost, the resulting surface shape of the workpiece obtained after the processing is unintentionally different between in its center side and outer circumference side, resulting in those portions incapable of satisfying the accuracy required. If this is the case, resultant semiconductor devices decrease in performance and hence fail to become initially expected ones while reducing processing yields and increasing product costs.

Techniques for improving the processing uniformity are known, one of which is disclosed, for example, in JP-A-2000-216140. The technique as taught thereby is such that a flow channel for permitting the flow of a refrigerant or coolant is formed within an aluminum electrode that makes up a wafer stage for use as a sample table, for appropriately adjusting by heat exchange of the coolant flowing in the channel a temperature of the aluminum electrode to thereby adjust a temperature of a wafer being mounted on the wafer stage. This prior art is aimed at achievement of uniformization of the processing on the wafer surface in its surface direction by making the wafer's temperature uniform in the wafer surface.

Another wafer temperature adjustment technique is disclosed in JP-A-7-172001, wherein a coolant flow channel is disposed within a lower electrode for use as a wafer support table in a similar way to the above-cited art, while having a heater for heatup of the lower electrode and the wafer to thereby adjust temperatures of the lower electrode and the wafer.

### SUMMARY OF THE INVENTION

While the above-noted prior art techniques are for adjusting on a case-by-case bases the temperature of a stage (lower electrode) which mounts thereon a wafer that is a workpiece or sample to thereby improve the processing accuracy and the pattern fabrication capability, these techniques fail to sufficiently take account of the influence of electrical power to be supplied to the sample table. For this reason, the prior known approaches are faced with a problem as to the lack of an ability to perform the processing with high accuracy.

More specifically, in the case of an apparatus which is designed to guide charged particles in a plasma formed within a processing chamber into the surface of a workpiece under treatment and utilize these particles to bring forward the processing so that a desired shape is obtained, a high frequency voltage is applied to an electrode that makes up the sample table in order to guide and collect together the charged particles in the plasma to thereby form on the workpiece surface a potential (bias potential) due to this high frequency power.

A problem in the prior art is as follows. Supplying such the high frequency power (bias power) would result in an increase in temperature of the sample table that is an electrode. A variation or fluctuation takes place in the processing to a degree corresponding to this temperature increase. Thus, the surface shape of a processed workpiece is changed from an expected shape to an arc-like shape.

Another problem is as follows. Although such sample table temperature increase occurs in association with the application of bias power, this bias power is such that a predetermined magnitude of electric power is applied per processing session of a workpiece being processed. Accordingly, the sample table increases and decreases in temperature upon start-up and completion of the processing of a respective workpiece. In accordance with the startup or termination of the application of this bias power or with increment/decrement of the sample table temperature, the processing characteristics can vary, resulting in occurrence of a variation in surface shape of the workpiece processed. This damages the uniformity of the processing.

A further problem is as follows. Even when an attempt is made to carry out such temperature variation of the sample table based on actions of a heat exchange medium flowing in the passage disposed inside of this sample table, there is a time lag in flowage of the heat exchange medium. Due to this, even when detecting a variation in sample table temperature and then adjusting the coolant's characteristics, such as its flow rate and temperature or else, in such a way as to suppress a temperature variation of the sample table, a certain length of time must be taken up to a change in temperature of the sample table. This can affect the processing during this duration, thereby deteriorating high accuracy processing.

It is therefore an object of this invention to provide plasma processing apparatus and method capable of performing the processing with high accuracy.

The above-noted object is achievable by providing a plasma processing apparatus which includes a processing chamber disposed within a vacuum vessel for causing a plasma to be formed therein, a sample table disposed beneath the processing chamber for mounting on its upper surface a workpiece to be processed, an electrode disposed inside of the sample table for allowing application of first high frequency power for adjustment of a surface potential of the workpiece, a passage disposed inside of the sample table for causing a heat exchange medium to flow therein, and a control device for adjusting a temperature of the heat exchange medium flowing in the passage. The workpiece is processed by use of a plasma created within the processing chamber under application of the first high frequency power. The control device starts to adjust, prior to application of the first high frequency power, the temperature of the heat exchange medium based on information of the high frequency power in such a way as to have a predetermined value.

The object is also achieved by arranging the apparatus so that prior to ignition of the plasma, the control device starts up temperature adjustment of the refrigerant in such a way as to have a predetermined value based on information of the first high frequency power.

Further, the object is attained by arranging the apparatus so that it further includes a ring-shaped conductive member disposed above the sample table along an outer circumferential side of a surface of the sample table on which the workpiece is mounted, for causing second high frequency power to be applied thereto, wherein the workpiece is processed using the plasma while adjusting the first high frequency power and the second high frequency power to a predetermined value or values.

Furthermore, the object is attained by arranging so that the first and second high frequency powers as distributed from a power supply are applied to the electrode and the conductive member respectively. Additionally, it is attained by arranging so that the conductive member is mounted over the sample table by way of a member which provides electrical insulation between the conductive member and the electrode.

In addition, the object is attained by providing a plasma processing method for mounting a workpiece to be processed on an upper surface of a sample table disposed at a lower portion of an interior of a processing chamber disposed within a vacuum vessel and for processing the workpiece by use of a plasma formed within the processing chamber while applying thereto first high frequency power for adjustment of a surface potential of the workpiece as disposed inside of the sample table, wherein the method includes the step of starting, prior to application of the first high frequency power, to adjust based on information of this high frequency power a temperature of a heat exchange medium flowing in a passage disposed inside of the sample table in such a way as to have a predetermined value.

Further, the object is attained by providing a plasma processing method which starts, prior to ignition of the plasma, to adjust based on information of the high frequency power a temperature of a heat exchange medium flowing in a passage disposed inside of the sample table in such a way as to have a predetermined value.

Further, the object is attained by a plasma processing method for use with equipment having a ring-shaped conductive member disposed above the sample table along an outer circumferential side of a surface of the sample table on which the workpiece is mounted, for causing second high frequency power to be applied thereto, wherein the workpiece is processed using the plasma while adjusting the first and second high frequency powers to a predetermined value(s).

Furthermore, the objective is attained by arranging the method so that the first and second high frequency powers as distributed from a power supply are applied to the electrode and the conductive member respectively.

Other objects, features and advantages of the invention will become apparent from the following description of the embodiments of the invention taken in conjunction with the accompanying drawings.

### BRIEF DESCRIPTION OF THE DRAWINGS

FIG. 1 is a top view diagram schematically showing a configuration of a plasma processing apparatus, which is a first embodiment of the present invention.

FIG. 2 is a longitudinal cross-sectional diagram pictorially showing a schematic configuration of a vacuum vessel and its periphery of the plasma processing apparatus shown in FIG. 1.

FIG. 3 is a longitudinal sectional diagram for pictorial representation of an internal structure of a specimen support table shown in FIG. 2.

FIGS. 4A and 4B are graphs each showing one example of a specimen table temperature change at the time of refrigerant temperature control using prior art techniques.

FIG. 5 is a graph showing an example of a specimen table temperature distribution in accordance with the embodiment shown in FIG. 1.

FIG. 6 is a vertical sectional diagram schematically showing a configuration of main part of a vacuum processing apparatus including a processing chamber and a sample table in accordance with another embodiment of the invention.

### DETAILED DESCRIPTION OF THE EMBODIMENTS

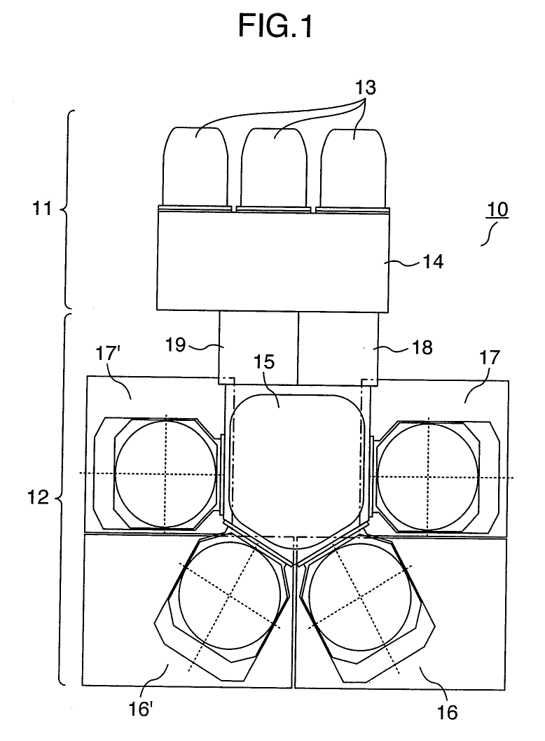

A first embodiment of this invention will be explained in detail with reference to FIGS. 1 to 5.

FIG. 1 is a top view diagram schematically showing an arrangement of a plasma processing apparatus in accordance with the first embodiment of the invention.

In FIG. 1, the plasma processing apparatus 10 of this embodiment is generally partitioned into an atmospheric air side block 11 which is at an upper part of this drawing sheet and a vacuum side block 12 at a lower part of the drawing.

The atmosphere side block 11 includes more than one cassettes 13 each of which is capable of receiving therein a plurality of substrate specimens or samples to be processed in this plasma processing apparatus 10, such as semiconductor wafers or else, and atmosphere-side transfer vessel 14 that the cassette is attached to a front face side of the apparatus, which becomes the upper side in this drawing. The atmosphere-side transfer vessel 14 has a conveyance chamber disposed therein, which is a space into which a sample within any one of the cassettes 13 is loaded and conveyed as a workpiece to be processed.

The vacuum-side block 12 includes a vacuum-side transfer vessel 15 which is disposed at a central portion and which has its planar shape of almost a polygon (in this embodiment, substantially a pentangular shape), and a plurality of vacuum vessels that are attached and coupled to side walls of the vacuum-side transfer vessel 15 corresponding to respective sides of the polygon.

More specifically, etching process units 16 and 16′ are provided at two side walls on the diagram lower side of the drawing sheet (apparatus backside) of the vacuum-side transfer vessel 15. Each etching process unit 16, 16′ includes a vacuum vessel having a processing chamber for permitting a workpiece to be etched in its inner space and its underlying bed structure that contains therein equipment required for the etching process within its inside processing chamber and an operation of the vacuum vessel. In addition, ashing process units 17 and 17′ are disposed at two side walls on the diagram's right and left sides (on the right and left sides of the apparatus) of the vacuum-side transfer vessel 15. Each ashing unit 17, 17′ includes a vacuum vessel having a processing chamber in which a workpiece is subjected to ashing process in its inner space and a bed for use with this vacuum chamber during ashing.

Furthermore, load lock chambers or unload lock chambers 18 and 19 are disposed between the atmosphere-side transfer vessel 14 and the vacuum-side transfer vessel 15, which chambers are vacuum vessels that are attached and coupled to side walls of these vessels for sending and receiving a workpiece to and from the vessels 14 and 15. In the illustrative embodiment, each of these load/unload lock chambers is arranged so that an unprocessed or processed workpiece is mounted therein while offering the capability for causing a pressure to vary between a high vacuum pressure, which is substantially equal to an internal pressure of the vacuum vessel within either each processing unit or vacuum-side transfer vessel 15, and an atmosphere pressure within the atmosphere-side transfer vessel 14 to thereby adjust it to a predetermined value. With such an arrangement, it is possible to transport a workpiece between the inside space of the atmosphere-side block 11 and that of vacuum-side block 12 in a way such that the workpiece is sent from one to the other, or vice versa.

Additionally, the load lock chambers or unload lock chambers 18 and 19 are similar in function to each other. Although whether a workpiece transfer direction is limited to a single direction or the workpiece is delivered in two opposite directions is settable on a case-by-case basis in accordance with specifications, the both will be simply called the load lock chambers hereinafter.

In the plasma processing apparatus 10 with the arrangement stated above, a workpiece or “sample” to be processed as stored in the cassette 13 is taken out of it and transferred by a robot arm (not shown) disposed within the transfer chamber in the atmosphere-side transfer vessel 14 to reach either load lock chamber 18 (or 19) through an opening that is disposed in a side wall of atmosphere-side transfer vessel 14, and is then mounted on a sample support table (not shown) which is disposed in the interior thereof.

After having sealed by shut-off of the opening, the interior of the load lock chamber 18 is evacuated so that its internal pressure decreases to a predetermined level, which is substantially equal to an internal pressure of the vacuum-side transfer vessel 15. After it is confirmed that the predetermined pressure is established, open the opening on the vacuum-side transfer vessel 15 side. Then, the robot arm (not shown) disposed within the vacuum-side transfer vessel 15 takes out the workpiece being put on the sample table within the load lock chamber 18 and then delivers it to the transfer chamber within the vacuum-side transfer vessel 15 for transportation into the processing chamber within the vacuum vessel of either processing unit—for example, the etching process unit 16. The workpiece thus transferred into the vacuum vessel is then mounted on the sample table within this vacuum vessel. After having shut off the opening which communicably couples together the inner space of the vacuum vessel of the etching process unit 16 and the transfer chamber within the vacuum-side transfer vessel 15, the workpiece is subject to etching process in the vacuum vessel.

After completion of the etching process, the opening is opened. The workpiece is transported in the order or direction opposite to the above. Alternatively, after having transferred to inside of the ashing process unit 17 (or 17′) and subjected to ashing process, the workpiece is sent to inside of the vacuum-side transfer vessel 15 and received in the original cassette 13 via the load lock chamber 18 (or 19).

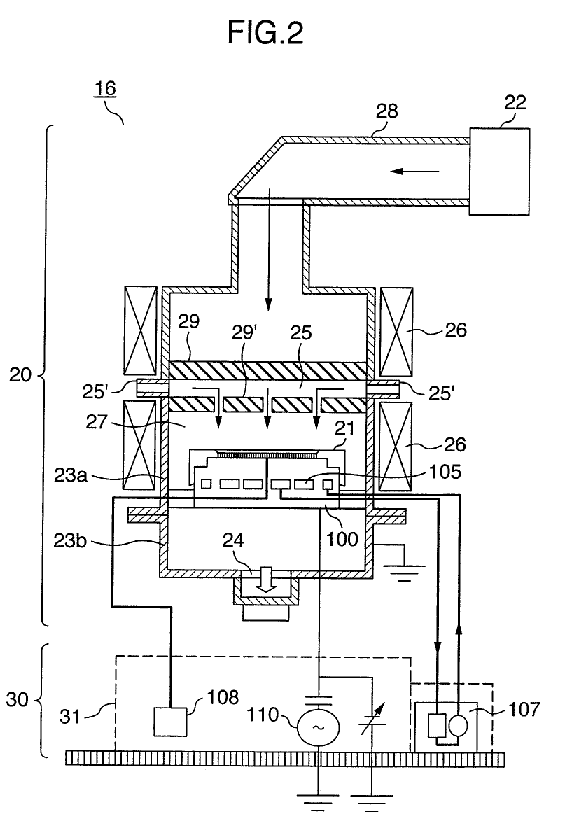

A configuration of the plasma processing apparatus embodying the invention will be explained in detail with reference to FIG. 2. FIG. 2 is a longitudinal cross-sectional diagram pictorially showing a schematic arrangement of a vacuum vessel of the plasma processing apparatus shown in FIG. 1 and its associated peripheral devices. In particular, FIG. 2 depicts the configuration of the etching process unit 16 shown in FIG. 1 and its periphery.

In FIG. 2, the etching process unit 16 is generally separated into two parts as stated previously. An upper part includes a processing unit 20 which includes a vacuum vessel and a processing chamber disposed inside of it. A lower part has a bed 30 containing therein equipment which is required for execution of the processing and operation of the processing chamber and vacuum vessel.

The processing unit 20 is supported over the bed 30 so that it is coupled to the bed 30 and the vacuum-side transfer vessel. In this embodiment, the bed 30 is designed so that it has an almost rectangular solid shape in a similar way to the other processing unit, thereby allowing, when performing maintenance works, servings or else, a user or an employee to ride on the processing unit 20 and easily perform his or her work operations.

The processing unit 20 has processing vessels 23a and 23b each consisting essentially of a vacuum vessel, and electromagnetic wave supplying devices which are disposed at a side circumferential portion 15- and upper portion thereof. A radio wave source 22 having a magnetron for creation of a micro wave(s) and a waveguide tube 28 connected thereto are disposed over the processing vessel 23a, for causing a micro wave to be introduced into the processing chamber 27 within the processing vessel 23a and its underlying vessel 23b as connected thereto. Furthermore, a magnetic field is generated by a solenoid coil 26 disposed around the processing vessel 23a and part of its overlying waveguide tube 28 and is then supplied to the interior of the processing chamber 27.

A microwave which is supplied from the upper part of the processing unit 27 through the waveguide tube 28 and an electric field created thereby are guided to pass through a flat plate-like window member 29, which is made of a dielectric material such as quartz or the like and which is placed over the processing chamber 27 for partition between it and an inner space of the waveguide 28, and are then introduced into the processing chamber 27. At a location underlying this window member 29 and facing the interior of the processing chamber 27, a shower plate 29′ is disposed with a gap space being defined between it and the window member 29. The gap between these parts is for use as a space for room 25, to which a processing gas is supplied for diffusion.

In this embodiment, the room 25 is communicably coupled to a gas supply pipe 25′ which is disposed at an upper side wall of the processing vessel 23a and is coupled through this gas supply pipe 25′ to a processing gas supply source (not shown).

A stage 21 is disposed within the processing chamber 27. This stage includes a sample support table 100, on which a workpiece or sample to be processed is mounted.

As previously stated, the processing gas that is supplied into the buffer booth from a plurality of gas inlet ports disposed in the shower plate 29′ is supplied to the interior of the processing chamber 27 from above the stage 21. In addition, the interior of processing chamber 27 is evacuated from an exhaust port 24 disposed in the bottom at lower part of the processing vessel 23b by a vacuum pump (not shown) that is coupled to this exhaust port 24, whereby the inner space of processing chamber 27, in which upper and lower spaces of the stage 21 are coupled together via a peripheral space of the stage 21, is adjusted to stay at a predetermined pressure while receiving introduction of the processing gas. In this state, the processing gas is energized by the action of an electric field or a magnetic field as supplied into a processing chamber 50 through the window member 29 and a wall member of the processing vessel 23a, resulting in a plasma being generated in a space over the stage 21 within the processing chamber 27. By adjustment of these electric and magnetic fields, a distribution of the plasma or its density or intensity is adjusted.

The stage 21 is disposed at a central portion within the processing vessel 23a having an almost cylindrical shape so that upper and lower inner spaces of the stage 21 within the processing chamber 27 are communicably coupled together by a space that is disposed between it and the side wall of the processing vessel 23a. Additionally, the stage 21 has a support beam for holding a sample mount part in the horizontal direction which extends in a lateral direction of the drawing sheet (almost horizontal direction). In addition, supply pathways or channels of electrical power and a fluid such as a gas to be supplied to the stage 21 are laid out inside of this support beam.

Within the sample table 100 that constitutes the stage 21, a refrigerant passage 105 in which a refrigerant or coolant, such as water or else flows, is disposed to have a concentric or spiral shape relative to the sample table 100 with the almost cylindrical shape in order to adjust a temperature of this sample table 100 and then adjust a temperature of a workpiece being mounted on this sample table 100. This refrigerant passage 105 has one end which is communicably coupled to a supply end side of a temperature adjuster 107 for adjusting a temperature of the coolant and the other end which is coupled to a flow-back end side of the temperature adjuster 107 through a flow path, thereby permitting the coolant from the temperature adjuster 107 to circulate in the refrigerant passage 105.

The coolant which was temperature-adjusted within the temperature adjuster 107 is introduced into the refrigerant passage 105 and then guided to flow through this passage 105 while performing heat exchange to thereby adjust a temperature of a base material 101 so that it becomes a desired value. After exiting from the refrigerant passage 105, the coolant returns from the flow-back side of the temperature adjuster 107 and is heated up or cooled down by the temperature adjuster 107 to reach a predetermined temperature, followed by re-introduction into the refrigerant passage 105.

Note here that the sample table 100 is supplied with electrical power from a high frequency power supply 110 and functions also as an electrode for setting a voltage potential of a workpiece being mounted thereover to a predetermined value with respect to a plasma created.

The temperature adjuster 107 and a tank for reservoir of the refrigerant and the high frequency power supply 110 or the like are housed in a storage vessel 31 making up the bed 30, which is of a substantially rectangular solid-like shape and which has an outer circumferential surface of a flat plane shape, thereby providing a space for enabling a maintenance worker to ride on the flat plate part of an upper surface thereof.

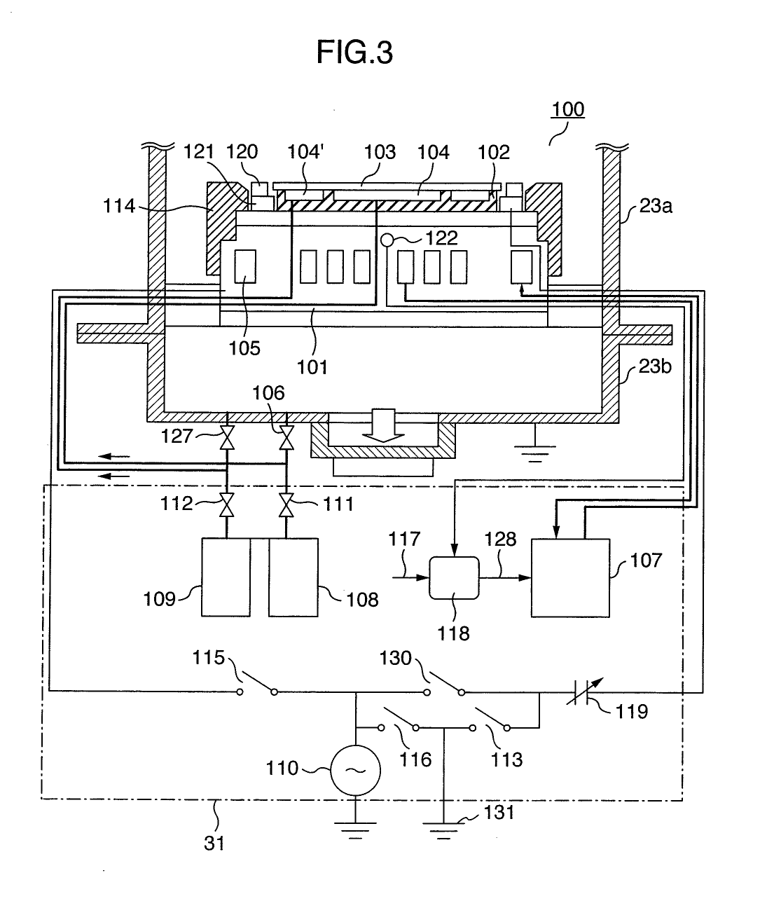

A detailed explanation will next be given of an arrangement of the sample table with reference to FIG. 3. FIG. 3 is a longitudinal sectional diagram pictorially representing an internal structure of the sample table shown in FIG. 2.

In FIG. 3, the sample table 100 is structured so that a plurality of members are stacked in the up-down direction. This table has an almost circular shaped base material 101 that is a major member and a film 102 made of a dielectric material which is disposed above the base material 101 and which covers an almost circular flat face on which a workpiece 103 is to be mounted. Note that this dielectric material-made film 102 has, on its top surface for mount of the workpiece 103, a plurality of concave portions and a plurality of protruded portions which partition these concave portions and which come into contact with a back side (lower side) surface of the workpiece 103.

In this embodiment, in the state that the workpiece 103 is mounted on the sample table 100, spaces that are disposed by the concave portions of the dielectric material film 102 are defined between a top surface of the dielectric film 102 and the back face of the workpiece 103. These spaces include two spaces which follow: a space 104 at a central portion of the sample table 100 (or the workpiece 103), and a space 104′ disposed around the space 104 on an outer circumference side thereof.

As stated supra, the refrigerant passage 105 is disposed within the base material 101 of the sample table 100 whereby temperature adjustment is done so that a temperature of the base material 101 is kept at a predetermined temperature. Further, a heat transfer gas, such as helium (He) or else, is supplied to the above-noted spaces 104 and 104′ for promoting heat transfer between the base material 101 of sample table 100 under temperature adjustment and the workpiece 103 whereby the workpiece 103 is adjusted so that its temperature becomes a desired temperature. In other words, the two inner and outer spaces 104, 104′ that are disposed in a radial direction of the workpiece 103 having the almost circular shape act as regions for heat transmission.

A heat transfer gas from a gas container for reservoir of the heat transfer gas is introduced into the inner circumference side space 104 of the sample table 100 after its pressure is adjusted by an adjustment valve 111. As for the space 104′ disposed on outer circumference side of the sample table 100, a heat transfer gas is introduced thereinto from a gas container 109 through an adjustment valve 112. The heat transfer gases in respective spaces are subjected to pressure adjustment in a way independent of each other so that the heat transfer in each corresponding region of the workpiece 103 is variably adjusted.

By appropriately adjusting or setting up the pressures of the heat transfer gases in this way, adjustment is done in such a way that a temperature distribution within the surface of the workpiece 103 becomes a desired distribution. Note here that although in this embodiment two ones 104 and 104′ are explained as the heat transfer gas supply spaces, the number of these spaces is not limited to that of this embodiment and may be different therefrom in accordance with specifications required or equivalents thereto—for example, it may be more than three (3) or one (1).

In the case of processing the workpiece 103, the predetermined temperature distribution of the workpiece 103 in its surface direction is adjusted by taking account of a distribution of reaction products, which are generated in a plasma or on the surface of the workpiece 103. More specifically, by raising higher the temperature of workpiece 103 at a location whereat there are many reaction products (i.e., density is high) to thereby suppress re-dipositing or re-adherence of the reaction products while on the other hand relatively lowering the temperature of workpiece 103 at a location with less reaction products, differences in process speed and micro-fabricated shape for the whole surface of the workpiece 103 are reduced so that the processing is uniformized.

For example, the generation of reaction products during etching process of a workpiece 103 often exhibits a distribution wherein many reaction products are found at a central portion of the workpiece 103 and these become gradually less in number with a decrease in distance to a peripheral portion of the workpiece. In this case, in order to optimize the workpiece temperature distribution for adaptation with the reaction product distribution, an attempt is made to set up the pressure of a heat transfer gas being supplied to the space between the workpiece 103 and the dielectric material film 102 so that a gas pressure in a center side space is less while becoming higher in a space on the outer circumference side, thereby further lessening transmission of the heat being supplied from the plasma to the workpiece 103 on the center side to thereby heighten a surface temperature at the central portion of the workpiece 103, resulting in establishment of a distribution with a further decrease in temperature at peripheral portions.

This temperature distribution is such that an adequate temperature distribution is affected by the type or kind of a workpiece and the reaction product exhaust speed and others. In accordance with these factors, the shapes and positions in radial directions of the heat transfer gas passage and the concave portions may be modified.

Additionally, for protection purposes of the sample table 100 or the base material 101 which is a conductive member made of aluminum or else, a susceptor 114 and conductive rings 120 and 121 are disposed on the outer circumference of the sample table 100. The susceptor 114 is made of an insulative material and is settled on the outer circumference side of the dielectric material film 102, which is a sample mount face on which a workpiece 103 is mounted. On its inner circumference side, the conductive rings 120 and 121 are laid out. The ring 121 is large in resistance for control of an electric field at the periphery of workpiece 103. Ring 120 is less in resistance for giving a voltage uniformly in a circumferential direction of ring 121.

Furthermore, a variable capacitor 119 is provided midway in a power feed path spanning from the high frequency power supply 110 up to the conductive ring 120. Appropriately adjusting this capacitor causes a voltage being applied to the conductive ring 120 to vary in potential to thereby adjust electric fields at and near the surface of the workpiece 103, thus making it possible to adjust the fabrication shape of workpiece 103 on its periphery side and the attachment of reaction products to outer circumferential portions of the sample table 100.

In this embodiment, one preferred case for performing distribution of bias power from the high frequency power supply 110 to the sample table 100 and its outer circumferential part is the case in which switches 115 and 130 are driven to turn on causing an output side end of the high frequency power supply 110 and the base material 101 and also the conductive ring 120 to be electrically connected together through the variable capacitor 119 while simultaneously causing switches 113 and 116 to turn off to thereby provide electrical isolation from earth 131. In this case, electric power of the high frequency power supply 110 is divided into power supplied to the base material 101 made up of a conductive member and power for the conductive ring 120 in accordance with a load ratio which is determinable by setup of the variable capacitor 119, thus having at a respective member a voltage potential that is determined between its overlying plasma and an electric field to be supplied to the processing chamber 27.

Additionally, one case the potential of the conductive ring 120 is set to 0V is that the switches 115 and 113 are driven to turn off while the switches 130 and 116 turn on, causing the output end of the high frequency power supply 110 to be electrically connected to the base material 101 while letting it be insulated from the earth 131 and also causing the conductive ring 120 to be connected via the variable capacitor 119 to the earth 131 while letting it be insulated from the high frequency power supply 110.

Although this embodiment is such that the electrical power to be supplied by the high frequency power supply 110 is divided into power being supplied to the base material 101 and bias power being fed to the conductive ring 120, this invention is applicable without being limited to such the structure.

Also note that the temperature adjuster 107, the high frequency power supply 110, the pressure control valves 111-112, a programmable controller 118, the variable capacitor 119 and the switches 113, 115, 116, 130 are connected to an apparatus control device (not shown) for generating and issuing signals indicative of their operation states, while simultaneously causing drive means thereof to be rendered operative in response to a command signal(s) from the apparatus control device so that output values, open/close, open degrees and others are set to predetermined states.

As previously stated, the coolant that was introduced into the refrigerant passage 105 within the base material 101 of the sample table 100 circulates along a route which follows: it passes through a predetermined range and then flows out of it and, thereafter, returns to the temperature adjuster 107 for adjustment of its temperature, flows out of it, and then flows into the refrigerant passage 105. By this coolant circulation, the temperature of the base material 101 is set to a predetermined level, resulting in the sample table 100 and a workpiece 103 mounted thereon being adjusted in temperature so that each has a predetermined value.

While the temperature of the base material 101 is such that its distribution is dominated in accordance with a temperature of the coolant within the refrigerant passage 105, a substantially uniform temperature distribution is established in the base material 101 of this embodiment which is formed of a metal with high thermal conductivity, such as aluminum or the like, with regard to the surface direction of the workpiece 103 being mounted thereover. The temperature of the workpiece 103 is adjusted in a way such that pressure values of the heat transfer gases being supplied to the spaces 101 and 104 that are heat transfer regions to be disposed at workpiece back surface side in a state that the workpiece 103 is mounted and a difference of these pressure values are used to make a difference in quantity and ratio of transmission toward the sample table 100 side of the heat being supplied from a plasma or else to the workpiece 103 in those regions corresponding to the spaces 101 and 104, thereby causing the temperature of workpiece 103 to have a desired distribution.

It should be noted that in the routes for supplying heat transfer gases (e.g., He) within the gas containers 108, 109 to the above-noted spaces 104, 104′, there are disposed purge passages for being branched from these routes and for communicably coupling together these routes and the inner space of the processing chamber 27 within the processing vessel 23b and purge valves 106, 127 disposed in these routes. These purge valves 106, 127 are normally closed during processing of the workpiece 103 and opened when unloading the workpiece 103 from above the sample table 100 or in case where a need is felt to exhaust gases in the spaces 104, 104′ and the heat transfer gas supply routes upon occurrence of abnormal conditions or accidents. In this event, a gas is introduced into the processing chamber 27, causing the gases within the processing chamber 27 to be exhausted toward outside of the processing vessel through an exhaust port 54, together with plasma particles and others.

Temperature adjustment of the temperature adjuster 107 will be explained in detail.

The temperature adjuster 107 is connected to the programmable controller 118, for receiving as a signal a command which was calculated therein and then issued therefrom. Based on the command of such signal, an operation is adjusted. The programmable controller 118 has therein a rewritable memory device. In accordance with an operation program as recorded in this memory device, commands are calculated relating to an operation of the temperature adjuster 107 and a temperature setup value.

Additionally, the programmable controller 118 is disposed within the base material 101 making up the interior of the sample table 100, which is connected to a temperature sensor 122 connected for detection of its temperature. The temperature sensor 122 is the one that detects and monitors a temperature of the base material 101 and sends out to the programmable controller 118 a voltage signal corresponding to the detected temperature. This signal may be an optical signal rather than an electrical signal such as the voltage or the like.

The programmable controller 118 sets up a temperature of the sample table 100 via the base material 101, while using a signal from the temperature sensor 122 to obtain a difference between the setup temperature and an actual temperature of the base material 101. Further, it uses such difference to calculate a coolant temperature to be adjusted at the temperature adjuster 107 and then send out a signal 128 that commands such temperature setup toward the temperature adjuster 107. In responding to this signal, the temperature adjuster 107 changes a temperature of the coolant flowing and circulating in the interior thereof.

Although in this embodiment such the coolant temperature adjustment is performed at all times during workpiece processing, the programmable controller 118 receives a signal 117 concerning the setup of its high frequency bias power to be applied before a radio frequency (RF) bias is applied to the base material 101 and then calculates a load to the sample table 100 based on the signal 117 thus received. Use this prediction result to send to the temperature adjuster 107 a signal 128 of a command as to either the setting of a coolant temperature or the setup of the coolant's flow rate prior to application of the high frequency bias. The command of this signal 128 is computed in such a way as to restrain or reduce the influenceability of the temperature of sample table 100 due to the bias power being applied.

Also note that in this embodiment, the command as to the signal 128 is computed and set in a way according to the magnitude and frequency of the high frequency bias. Especially in this embodiment, the bias power from the high frequency power supply 110 is supplied while being distributed to the base material 101 of sample table 100 and the dielectric material film 102 along with the conductive ring 120 which is disposed on the outer circumference side of a workpiece 103 disposed thereover. Upon receipt of a signal 117 concerning the setup information of part of such bias power which is electrical power to be applied to the base material 101, a detection result of this received signal is taken into consideration so that a temperature of the coolant is set by the temperature adjuster 107 and an operation of the temperature adjuster 107 is set up.

For example, the programmable controller 118 is such that its internal calculating processor device uses an output signal from the temperature sensor 122 and the signal 117 indicating the information of a distribution ratio of the electrical power being supplied to the conductive ring versus the electric power being fed to the base material 101 that is the electrode of sample table 100 to predict and compute a change in temperature of the base material 101 due to application of the bias power based on a software program as stored in the memory device, and then calculate the coolant temperature required for reduction of this change. A signal 128 of a setup command for realizing this calculated temperature is generated and sent forth to the temperature adjuster 107.

In this embodiment, during the process for a workpiece 103 that is presently settled within the processing chamber 27, it is possible to vary the distribution ratio of a voltage “A” which is generated at the base material 101 of the sample table 100 versus a voltage “B” of the power feed ring 120 or alternatively the distribution ratio of high frequency power being supplied to the base material 101 and that being fed to the power feed ring 120.

One of the electrical power components to be supplied to respective members in this distribution fashion or those voltages as generated thereby, which significantly affects the actual workpiece temperature control, is the electric power being supplied to the base material 101—that is, the voltage “A”. In other words, the potential of the base material 101, which has a surface for mounting thereon a workpiece 103 and which functions as an electrode for giving a potential to the workpiece 103, exerts a dominant influence on the speed and quantity of charged particles in a plasma which are induced and attracted to the workpiece 103 to thereby affect the temperature of workpiece 103 and the process properties.

In this embodiment, the ratio of certain one of bias power components to be supplied for temperature control of the sample table 100 or its base material 101 and the workpiece 103—i.e., the power being supplied to the base material 101—or the ratio of the voltage “A” generated by this bias power is given to the programmable controller 118 by the control device (not shown) so that a setup coolant temperature at the temperature adjuster 107 is calculated.

In this embodiment, with such an arrangement, the temperature of the base material 101 is adjusted to become a desired value whereby the sample table 100 stays at a predetermined temperature so that the surface temperature of a workpiece 103 being mounted above the sample table 100 is adjusted to have a desired value.

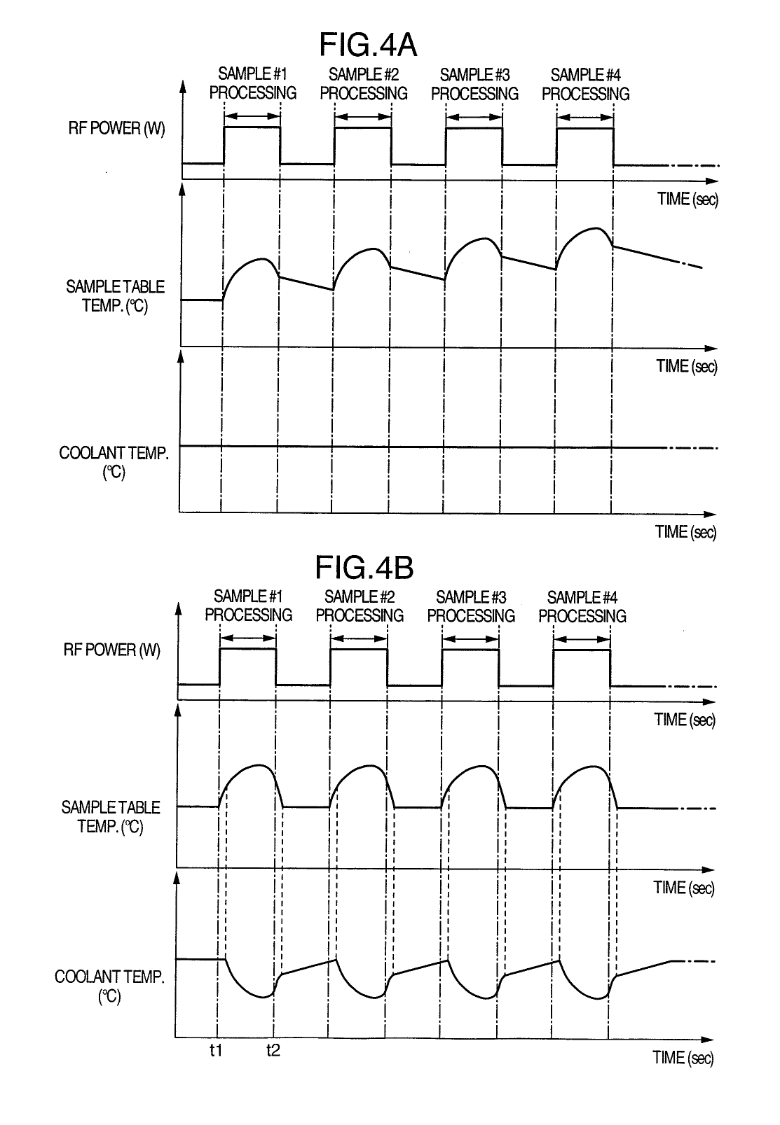

See FIG. 4A, which graphically shows an example of a change in sample table temperature in a case where adjustment is done by a prior art technique so that the coolant temperature remains constant.

As shown in this graph, in case the coolant temperature is simply adjusted to stay at a fixed level, the temperature of the sample table 100 increases upon application of a high frequency bias being supplied to this sample table 100, and begins to drop down when the supply of such high frequency power goes off. Furthermore, during workpiece process, the temperature gradually decreases due to a temperature difference from the temperature-constant coolant that flows for circulation in the flow path. However, the temperature does not drop down to an initial temperature prior to startup of the workpiece process, and again increases when the next workpiece process gets started. With an increase in number of workpieces to be processed, the sample table gradually increases in temperature, resulting in an increase in workpiece temperature. This can be said because the temperature of the sample table 100 fails to be set in a steady state. Generally speaking, after having processed a plurality of workpieces, the temperature of sample table 100 becomes an equilibrium state determinable by the load of a bias due to the high frequency power supplied and the heat input from a plasma and a surrounding member(s) and the heat transfer amount to the coolant so that it becomes an almost constant temperature.

However, this results in occurrence of a variation in after-fabrication shape obtained as a result of the processing among workpieces to be processed. Accordingly, a difference of fabrication shape between an initial workpiece at the time the processing gets started and a later obtained workpiece becomes greater, resulting in a decrease in production yields and/or an increase in manufacturing costs.

FIG. 4B is a graph showing one example of a temperature change of the sample table 100 when a temperature of the base material 101 is feedback-controlled to the temperature adjuster 107 while the temperature sensor 122 is buried in the base material 101 within the sample table 100. This is an adjustment technique for monitoring the temperature of the sample table 100 and for lowering, upon occurrence of a difference from a preset temperature, the coolant temperature in such a way as to eliminate such difference.

With this technique, there are a time delay until arrival of the coolant from the temperature adjuster 107 to the refrigerant passage 105 within the base material 101 of the sample table 100 and a time delay from a change in coolant temperature up to an actual change in temperature of the sample table 100 or workpiece 103. Due to these time delays, as shown in FIG. 4B, the temperature of the sample table 100 always behaves to increase after application of input high frequency power and thereafter decreases. In addition, the temperature is adjusted to return at the temperature prior to processing startup until the startup of the next workpiece process, thereby suppressing undesired increase in sample table temperature and riseup of workpiece temperature due to an increase in number of workpieces processed. Unfortunately, suppression of temperature fluctuations after the processing startup is not enough. For this reason, the processed workpiece shape is not adjusted accurately. This can lower manufacturing yields.

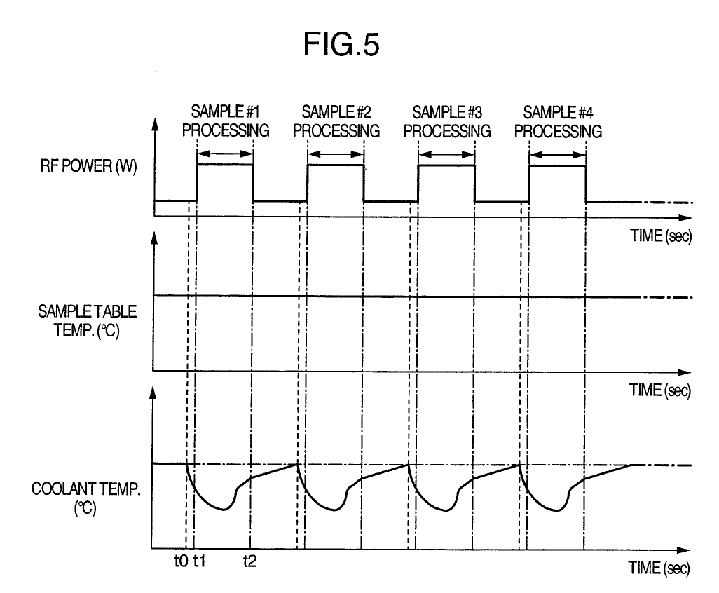

Referring next to FIG. 5, there is shown as a graph one example of a temperature change of the sample table 100 when the processing is performed using adjustment for lowering in advance the coolant's temperature (feed forward control) while letting a temperature of the sample table 100 be fed back to the temperature adjuster 107 and at the same time pre-detecting application of a bias due to high frequency power.

In this embodiment, adjustment gets started for lowering before the elapse of a predetermined time of the application of high frequency power while monitoring for detection of a temperature of the sample table 100 or its change by the temperature sensor 122 and making adjustment for lowering the coolant's temperature in such a way as to reduce a difference from a preset temperature.

Although a timing for startup of lowering is different depending upon either the thermal capacity of the sample table 100 or the magnitude of bias power, a time point at which the temperature of sample table 100 begins to drop down with the coolant temperature being set at a predetermined level, which is obtained in advance resulting from e.g. some experiments is stored in the memory device within the control device (not shown) or the programmable controller 118. When obtaining the information as to the application of high frequency power or when the programmable controller 118 receives the signal 117, an appropriate timing prior to application (estimated startup time) is extracted or read from within this stored information.

With such an arrangement, the application of a bias due to high frequency power is done accurately at or near the timing whereat either the sample table 100 or the base material 101 begins to decrease in temperature. Thus it is possible to control so that the sample table 100—in particular, a nearby portion of the workpiece 103—stays constant in temperature in any events while avoiding excessive decrease in temperature of the sample table 100. Whereby, any variation or deviation of the fabrication shape among processed workpieces is reduced, thus restraining a decrease in production yields also.

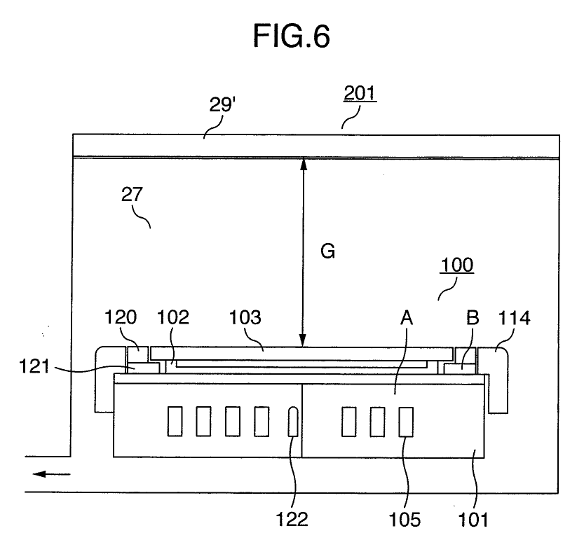

FIG. 6 is a longitudinal cross-sectional diagram schematically showing an arrangement of main parts of a processing vessel and sample table of a vacuum processing apparatus in accordance with another embodiment of the invention. In FIG. 6, a difference from the arrangement of the processing vessel 16 in accordance with the embodiment shown in FIG. 2 is that the shower plate 29′ which makes up the ceiling face of the processing chamber 27 over a workpiece 103 is replaced by a plate-shaped upper electrode 201, to which electrical power is applied.

This upper electrode 201 may alternatively be designed so that a plurality of openings or holes for introduction of a processing gas or gases into the processing chamber 27 in a similar way to the shower plate 29′. Optionally, the upper electrode 201 may be designed as an electrically conductive or semiconductive member having its upper and lower structures similar to those of the window member 29 and shower plate 29′ shown in FIG. 2 or alternatively as a plate-like member made of a dielectric material having on its upper side a conductive or semiconductive electrode and also having on its lower side a shape capable of transferring an electric field from the upper electrode toward the interior of the processing chamber 27, thereby having therein a room 25 in a similar way to the embodiment of FIG. 2.

In FIG. 6, there are shown a voltage “A” of high frequency power to be supplied to a base material 101 making up the sample table 100, a voltage “B” of high frequency power being supplied to a power feed ring 120 which is disposed at an outer circumference of either a workpiece 103 that is mounted on a top surface of the sample table 100 or a dielectric material film 102 making up the workpiece 103's mount surface, and a gap “G” defined between an upper surface of the workpiece 103 or the dielectric material film 102 and the upper electrode 201.

As in the above-noted embodiment of FIG. 2, it is possible in FIG. 6 also to vary the distribution ratio of the voltage A as generated at the base material 101 of sample table 100 versus the voltage B of the power feed ring 120 or the distribution ratio of high frequency power being supplied to the base material 101 and power being fed to the power feed ring 120.

The ratio of certain one of the electrical power to be supplied to each member while being distributed in this way or alternatively the voltage as generated thereby—that is, the ratio of the power being supplied to the base material 101 or of the voltage A that is generated by this bias power—is used to calculate a setup value of the coolant temperature at the temperature adjuster 107 by a control device (not shown).

In addition, a component which faces a plasma, such as the shower plate 29′ for uniformly supplying to a workpiece a gas which underlies the upper electrode 201, is such that a bias voltage is generated by penetration of an electric field from upper part and supply to the processing chamber 27 or by application of electric power to the shower plate 29′ per se. Accordingly, mutual interaction with particles within the plasma is greater than that of other members within the processing chamber and thus wastage takes place at relatively greater speeds.

Due to this, as process-applied workpieces 103 become greater in number, the distance G between the upper surface of the sample table 100 and the upper electrode 201 changes whereby the distribution of an electric field or else to be introduced into the processing chamber 27 can vary between an initial one upon startup of the processing and a later obtained one. This leads to occurrence of a significant difference in characteristics and resultant processed shapes between the process of a one lot of workpieces at the initial stage and the process of workpieces obtained thereafter, resulting in occurrence of a risk as to noticeable degradation of the yield of the processing.

In this embodiment, in order to restrain occurrence of the above-noted problem, the gap G is adjusted to make the electric field distribution within the processing chamber 27 more uniform through a wafer lot(s) or during time intervals for replacement of parts. More specifically, let the sample table 100 move to come closer to its overlying upper electrode 201 in accordance with an amount of wastage of the upper electrode 201 (shower plate 29′). Especially in this embodiment, the gap G between the top surface of workpiece 103 or dielectric material film 102 and the back surface of upper electrode 201 facing a plasma is specifically designed to restrain its variation during a one lot or within a time period up to parts replacement.

As the shower plate 29′ or the upper electrode 201 being exposed to the plasma is changing at any time with a progress of the processing, the sample table 100 is arranged to have a structure capable of moving upward and downward.

In case the gap G is adjusted in the way stated above, the load due to a bias being actually applied to the sample table 100 varies in conjunction with the gap G.

While taking account of the above, a setup signal 117 concerning the distribution of high frequency bias in proportion to the value of high frequency bias×(A/(A+B))×(kG) is generated and sent to the programmable controller 118 and then a height position of the top surface of the sample table 100, workpiece 103 or dielectric material film 102 is adjusted based on a signal of a command as to the amount of height movement of the sample table 100, which is calculated and generated by the programmable controller 118. Thus it is possible to implement uniform processing for an increased length of time period in the arrangement for applying a high frequency bias to the plasma-facing member above the sample table such as the processing unit 16 for performing etching process.

Note here that the supply of a refrigerant or coolant using a temperature adjuster that performs temperature control of the stage 21 is similar to that of the embodiment shown in FIG. 2, and an explanation thereof is omitted.

Examples of a plasma generation source include, but not limited to, a capacitive coupling source, an inductive coupling source, and an electron cyclotron resonance (ECR) source using microwaves or ultra-high frequency (UHF) waves, although not limited to plasma generation methodology.

While the above-stated embodiments are discussed by taking the plasma etching apparatus as an example, the principal concept of this invention is widely applicable to other types of processing apparatus in which workpieces or samples, such as semiconductor wafers or substrates, are processed in a low pressure environment while being heated up. Typical examples of the processing apparatus utilizing a plasma are a plasma etching apparatus, a plasma chemical vapor deposition (CVD) apparatus, and a sputtering apparatus. Additionally, examples of processing apparatus without use of a plasma include an ion implantation, molecular beam epitaxy (MBE), vapor deposition, low-pressure CVD (LPCVD) and others.

As in the embodiments stated supra, the quantity concerning the high frequency power to the sample table center part is given as an input signal in accordance with the information as to the distribution of high frequency power toward the power feed ring at outer periphery of the sample table and the sample table center part while causing either the temperature adjuster or the programmable controller to create a control signal after computation of the computation of setup conditions for adjustment of the temperature within the sample table, thereby adjusting the temperature of the sample table or workpiece in such a way as to have a desired value even upon occurrence of a variation in load to the temperature of the sample table. With such an arrangement, a temperature difference is reduced or minimized among a plurality of workpieces to be processed. Thus it becomes possible to achieve the processing with a less number of defective products and with improved yields and throughputs. It is also possible to perform workpiece process with enhanced accuracy.

Additionally, in case no bias is applied to the power feed ring side, an entirety of the bias being fed to the sample table contributes to the workpiece temperature so that the above-stated highly accurate workpiece processing further increases in accuracy.

Additionally, the signal relating to the input heat amount toward the sample table side in accordance with the degree of a gap between the sample table and the upper electrode is sent to either the programmable controller or the control device. After computation of an operation at this programmable controller or the control device, a command signal for setup or adjustment of a desired position in the height direction of the sample table is passed to a drive device of the sample table. In a way corresponding to a variation in amount of the load due to the bias in conformity with the gap, the sample table is adjusted in position so that adjustment is attained in such a way as to restrain its temperature change or suppress a variation of the load. With such an arrangement, a variation of temperature during process of a plurality of workpieces is reduced, thereby enabling achievement of the processing with a decreased number of defective products and with an increased microfabrication yields. It is also possible to achieve workpiece process with high accuracy.

It should be further understood by those skilled in the art that although the foregoing description has been made on embodiments of the invention, the invention is not limited thereto and various changes and modifications may be made without departing from the spirit of the invention and the scope of the appended claims.

1-10. (canceled)

11-16. (canceled)

17. A plasma processing apparatus, comprising:
a processing chamber which is disposed within a vacuum vessel, a plasma being generated within the processing chamber;
a sample table which is disposed within the processing chamber at a lower portion thereof, a workpiece to be processed being disposed on an upper surface of the sample table;
an electrode which is disposed inside of the sample table, the electrode being applied with a first high frequency power for adjusting a surface potential of the workpiece during the process of the workpiece;
a plate member which is disposed above the upper surface of the sample table within the vacuum vessel, the plate member being exposed to the plasma and applied with a second high frequency power; and
a control device which adjusts a height of the sample table to thereby adjust a gap between the upper surface of the sample table and the plate member in accordance with an amount of wastage of the plate member.

18. A plasma processing apparatus according to claim 17, wherein the control device adjusts the height of the sample table based on information of an amount of the first high frequency power.

19. A plasma processing apparatus according to claim 17, wherein the control device adjusts the height of the sample table so as to restrain a variation of the gap between the upper surface of the sample table and the plate member during the processing of a plurality of the workpieces, in accordance with the amount of wastage of the plate member.
